(19) United States
(12) Patent Application Publication
(10) Pub. No.: US 2003/0047810 A1
(43) Pub. Date: Mar. 13, 2003

(54) Electronic device having multilayer interconnection structure

(75) Inventors: Hitoshi Maeda, Tokyo (JP); Fumihito Ohta, Tokyo (JP); Koji Fukumoto, Tokyo (JP); Yoji Mashiko, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/171,600

(22) Filed: Jun. 17, 2002

(30) Foreign Application Priority Data
Sep. 10, 2001 (JP) 2001-273416

(51) Int. Cl. H01L 23/48

(52) U.S. Cl. 257/758

(57) ABSTRACT

An insulating film provided on an underlying layer (1) is selectively removed, thereby forming an insulating columnar body (4) standing on the underlying layer (1). A conductive film (7) is provided to cover the columnar body (4). Next, an interlayer insulating film (9) is provided to bury the columnar body (4) and the conductive film (7). The upper surface of the interlayer insulating film (9) is polished and planarized to the extent that the conductive film (7) is exposed. Thereafter an upper interconnect line (10) is provided. A lower interconnect line (8) and the upper interconnect line (10) are thereby connected through the conductive film (7).

### BACKGROUND OF THE INVENTION

1. Field of the Invention

The present invention relates to an electronic device having a multilayer interconnection structure which preferably is a semiconductor device, for example. More particularly, it relates to the improvement for realizing favorable connection between a plurality of interconnect lines while allowing microstructure of a device element.

2. Description of the Background Art

According to a technique in the background art for manufacturing a semiconductor device having a multilayer interconnection structure, it has been required to form a contact hole in an interlayer insulating film to be arranged on a lower interconnect line by selective anisotropic etching and fill the contact hole with a conductive material, thereby providing a plug for establishing connection between a plurality of interconnect lines.

On the other hand, the trend for microstructure of a device element such as transistor involves downsizing of the contact hole in diameter. Accompanied by this, it has been difficult to bury the plug without degradation in connectivity. As a countermeasure thereto, connection between the plurality of interconnect lines to be established without following the step of filling the contact hole with the conductive material should easily meet the need for microstructure of the device element.

### SUMMARY OF THE INVENTION

It is therefore an object of the present invention to provide an electronic device for realizing favorable connection between a plurality of interconnect lines while allowing microstructure of a device element.

A first aspect of the present invention is directed to an electronic device having a multilayer interconnection structure. The structure includes an underlying layer, a patterned lower interconnect line, an interlayer insulating film, an upper interconnect line, a tubular conductive film and an insulating columnar body. The lower interconnect line is provided on the underlying layer. The interlayer insulating film is provided on the underlying layer and the lower interconnect line. The upper interconnect line is provided on the interlayer insulating film. The tubular conductive film penetrates the interlayer insulating film to establish connection between the lower interconnect line and the upper interconnect line. The insulating columnar body is buried in a hollow of the conductive film and standing on the lower interconnect line.

The insulating columnar body standing on the lower interconnect line is easily formed by a background technique that selectively removes the insulating film. The lower interconnect line and the upper interconnect line are connected through the conductive film of a tubular configuration for surrounding the columnar body. As a result, it is allowed to establish connection between the lower interconnect line and the upper interconnect line without the step of filling a contact hole with a conductive material.

A second aspect of the present invention is directed to an electronic device having a multilayer interconnection structure. The structure includes an underlying layer, a patterned lower interconnect line, an interlayer insulating film, an upper interconnect line, a tubular conductive film and a columnar body. The lower interconnect line is provided on the underlying layer and has polycrystalline semiconductor doped with an impurity as a material. The interlayer insulating film is provided on the underlying layer and the lower interconnect line. The upper interconnect line is provided on the interlayer insulating film. The tubular conductive film penetrates the interlayer insulating film to establish connection between the lower interconnect line and the upper interconnect line. The columnar body is buried in a hollow of the conductive film and standing on the lower interconnect line, and has semiconductor doped with an impurity as a material.

Both the lower interconnect line and the columnar body standing thereon include semiconductor doped with an impurity as a material. Therefore, the columnar body is easily formed on the lower interconnect line by crystal growth. The lower interconnect line and the upper interconnect line are connected through the conductive film of a tubular configuration for surrounding the columnar body. As a result, it is allowed to establish connection between the lower interconnect line and the upper interconnect line without the step of filling a contact hole with a conductive material. Further, as the columnar body is also conductive, the lower interconnect line and the upper interconnect line can be connected with low resistance through both the columnar body and the conductive film.

A third aspect of the present invention is directed to an electronic device having a multilayer interconnection structure. The structure includes an underlying layer, a patterned lower interconnect line of a two-layer structure, an interlayer insulating film, an upper interconnect line, a tubular conductive film and a columnar body. The lower interconnect line is provided on the underlying layer and has a first layer and second layer portions. The first layer portion is a semiconductor crystal grain layer or a polycrystalline semiconductor layer doped with an impurity. The second layer portion is provided on the first layer portion. The interlayer insulating film is provided on the underlying layer and the lower interconnect line. The upper interconnect line is provided on the interlayer insulating film. The tubular conductive film penetrates the interlayer insulating film to establish connection between the upper interconnect line and the second layer portion and has a same material as the second layer portion. The columnar body is buried in a hollow of the conductive film and standing on the first layer portion. The columnar body has semiconductor doped with an impurity as a material.

Both the first layer portion of the lower interconnect line and the columnar body standing thereon include semiconductor doped with an impurity as a material. Therefore, the columnar body is easily formed on the first layer portion by crystal growth. The second layer portion of the lower interconnect line and the upper interconnect line are connected through the conductive film of a tubular configuration for surrounding the columnar body. As a result, it is allowed to establish connection between the lower interconnect line and the upper interconnect line without the step of filling a contact hole with a conductive material. Further, as the columnar body is also conductive, the lower interconnect line and the upper interconnect line can be connected with low resistance through both the columnar body and the conductive film. Still further, it is allowed to keep resistance low as well in the lower interconnect line having a two-layer structure.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 9 are views illustrating the steps of a manufacturing method according to a first preferred embodiment of the present invention;

FIGS. 10 through 16 are views illustrating the steps of a manufacturing method according to a second preferred embodiment of the present invention;

FIGS. 17 through 22 are views illustrating the steps of a manufacturing method according to a third preferred embodiment of the present invention;

FIGS. 23 through 27 are views illustrating the steps of a manufacturing method according to a fourth preferred embodiment of the present invention; and

FIGS. 28 through 34 are views illustrating the steps of a manufacturing method according to a fifth preferred embodiment of the present invention.

### DESCRIPTION OF THE PREFERRED EMBODIMENTS

In each of the preferred embodiments of the present invention described later, a semiconductor device is taken as an example of an electronic device. However, the electronic device according to the present invention is not limited to a semiconductor device having a multilayer interconnection structure mounted on a semiconductor substrate. Rather, the present invention may be applicable to other type of electronic device such as an LCD (liquid crystal display) as long as the device has a multilayer interconnection structure. Further, an “underlying layer” described in the present specification and claims widely refers to a base layer to be disposed under a lower interconnect line for constituting the multilayer interconnection structure. Still further, the lower interconnect line is not limited to a lowest layer of the multilayer interconnection structure but rather, it may be an arbitrary interconnect layer except an uppermost layer. That is, the underlying layer can also be an interlayer insulating film for providing insulation between interconnect layers of the multilayer interconnection structure.

First Preferred Embodiment

FIGS. 1 through 9 are views illustrating the steps of a method of manufacturing a semiconductor device according to the first preferred embodiment of the present invention. First, the method provides an insulating film 2 on an underlying layer 1 as illustrated in FIG. 1. The underlying layer 1 is an interlayer insulating film provided on a semiconductor substrate not shown, for example, including SiO₂ or Si₃N₄ as a material. The insulating film 2 may be a silicon oxide film which grows to a thickness of 500 nm, for example. Next, a mask 3 is formed on the insulating film 2 to have an island configuration using a known lithography technique. For example, the mask 3 is a resist film or alternatively, it may be a film having a high etching selectivity ratio relative to that of the insulating film 2. A silicon nitride film, for example, can be employed as a film having a high etching selectivity ratio relative to that of the silicon oxide film. The width of the mask 3 (corresponding to a diameter when it is circular in cross section) is set to be 50 nm, for example. The structure described so far is as given in FIG. 1.

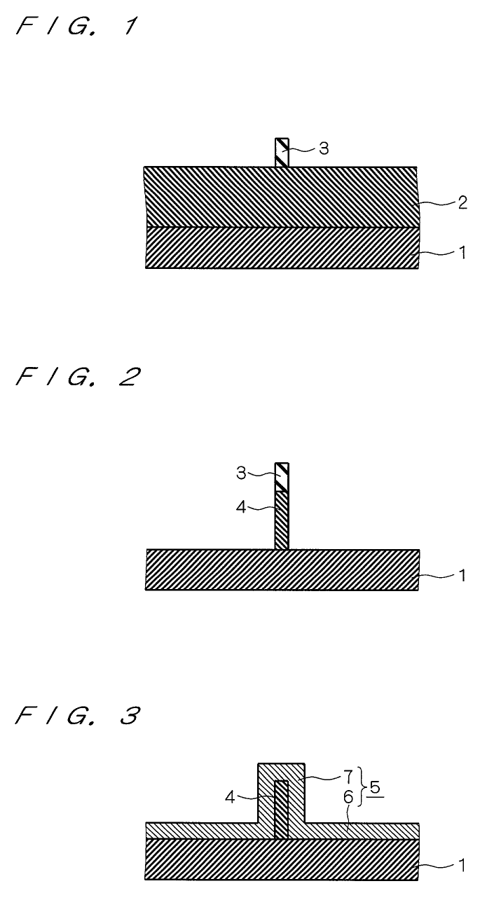

The subsequent step in FIG. 2 is anisotropic etching using the mask 3 to selectively remove the insulating film 2. As a result, an insulating columnar body 4 is formed standing on the underlying layer 1. The columnar body 4 is designed to have a width of 50 nm a height of 500 nm, for example.

Next, a conductive film 5 is provided to cover the underlying layer 1 and the columnar body 4 in a skin-like manner as illustrated in FIG. 3. Namely, the conductive film 5 covering the underlying layer 1 and the columnar body 4 has a thickness smaller than the height of the columnar body 4. As the conductive film 5 should cover the side surfaces of the columnar body 4, it is desirable that the conductive film 5 is made of a material exhibiting some degree of excellence in coverage characteristic. For this reason, the conductive film 5 is provided by depositing metal such as tungsten exhibiting excellence in coverage characteristic or the alternative including tungsten as a main constituent. A portion 6 of the conductive film 5 defined to cover the underlying layer 1 grows to a thickness such as 200 nm. Designating a tubular portion of the conductive film 5 defined to cover the columnar body 4 that is to be buried in a hollow thereof as a portion 7, the area of the portion 7 for covering the side surfaces of the columnar body 4 is designed to have a thickness that is determined depending on coverage characteristic. When the coverage characteristic is so controlled that the conductive film 5 has a thickness on the side surfaces of the columnar body 4 that is half the size of the thickness thereof on the underlying layer 1, the thickness of the conductive film 5 in the area for covering the side surfaces of the columnar body 4 is 100 nm, for example. In this case, the total width including the columnar body 4 and the conductive film 5 is 250 nm.

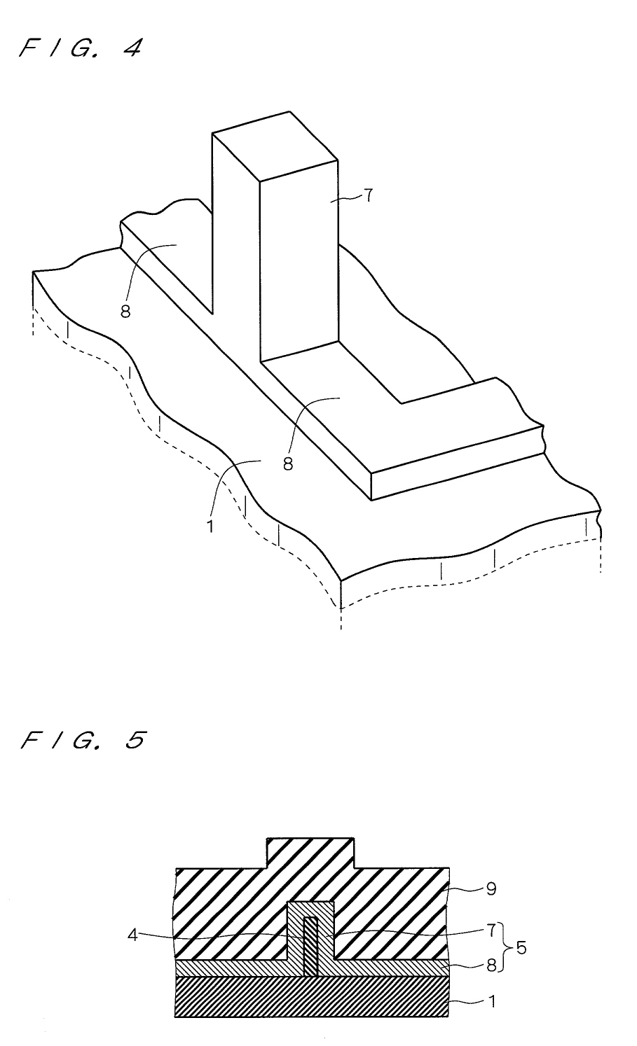

Thereafter the portion 6 of the conductive film 5 for covering the underlying layer 1 is patterned to form a lower interconnect line 8 as illustrated in FIG. 4. The patterning of the portion 6 is performed through a known technique using a mask pattern, for example. In FIG. 4, the columnar body 4 is shown to be rectangular in cross section. The lower interconnect line 8 is designed to have a width such as 500 nm.

Next, an interlayer insulating film 9 is provided on the underlying layer 1 to bury the columnar body 4 and the conductive film 5 as illustrated in FIG. 5. The interlayer insulating film 9 provided by depositing a silicon oxide film, for example, grows to have a thickness such as 1000 nm.

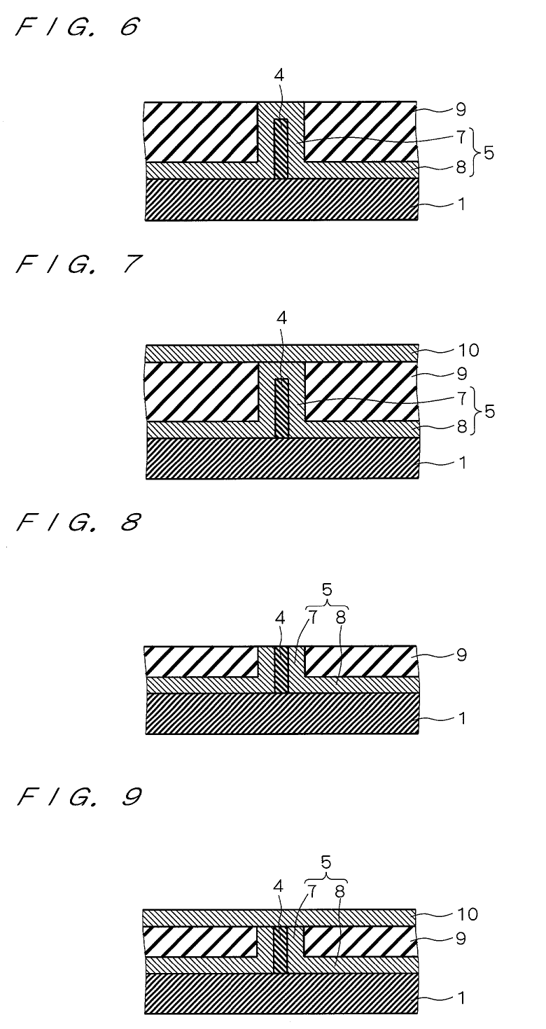

The subsequent step in FIG. 6 is polishing of the upper surface of the interlayer insulating film 9 to the extent that the tubular portion 7 of the conductive film 5 is exposed yet no exposure of the lower interconnect line 8 occurs. The upper surface of the interlayer insulating film 9 is thereby planarized. The amount of polishing is defined to have a range such as from 500 nm to 700 nm. In FIG. 6, the amount of polishing is so controlled that no exposure of the columnar body 4 occurs so that the head of the columnar body 4 is still covered with the conductive film 5 after polishing.

Subsequent to the above, an upper interconnect line 10 is provided on the interlayer insulating film 9 in such a manner that the upper interconnect line 10 is connected to the tubular portion 7 of the conductive film 5 as illustrated in FIG. 7. The upper interconnect line 10 is made of metal such as tungsten or the alternative including tungsten as a main constituent. The thickness and the width of the upper interconnect line 10 are respectively set to be 500 nm and 200 nm, for example.

As illustrated in FIG. 8, the amount of polishing may also be controlled in the polishing step of the upper surface of the interlayer insulating film 9 to the extent that exposure of the columnar body 4 is also given. According to this amount of polishing, connection between the upper interconnect line 10 to be provided in the subsequent step in FIG. 9 and the conductive film 5 is established only through the area of the conductive film 5 for covering the side surfaces of the columnar body 4.

Following the foregoing steps of the manufacturing method, connection between the lower interconnect line 8 and the upper interconnect line 10 can be established without the step of filling a contact hole with a conductive material. As a result, favorable connectivity can be obtained while meeting the need for microstructure of the device element. Further, the method simultaneously providing the conductive film 7 for connecting the lower interconnect line 8 and the upper interconnect line 10 and the lower interconnect line 8 results in simplification of the manufacturing steps. Still further, according to the structure obtained in FIG. 7, the tubular portion 7 is of a closed-tube configuration having an end closed for covering the head of the columnar body 4 to which the upper interconnect line 10 is connected. Therefore, it is allowed to keep resistance low in the connection between the conductive film 5 and the upper interconnect line 10.

Second Preferred Embodiment

FIGS. 10 through 16 are views illustrating the steps of a method of manufacturing a semiconductor device according to the second preferred embodiment of the present invention. In FIGS. 10 through 16, the same elements as or the corresponding elements to (elements having the same functions as) those in the first preferred embodiment are designated by the same reference numerals and the detailed description thereof will be omitted. Further, the dimension of each element such as film thickness and height of columnar body as exemplified in the first preferred embodiment is followed in the second through sixth preferred embodiments and therefore, the description thereof will be omitted.

First, the patterned lower interconnect line 8 is formed on the underlying layer 1 as illustrated in FIG. 10. The lower interconnect line 8 may provided by depositing a material for the lower interconnect line 8 on the underlying layer 1 to form a film and then patterning the same using a known technique. Thereafter the insulating film 2 is provided on the underlying layer 1 to bury the lower interconnect line 8. Next, the mask 3 is provided on the insulating film 2 to have an island configuration. The mask 3 is located directly above the part of the lower interconnect line 8.

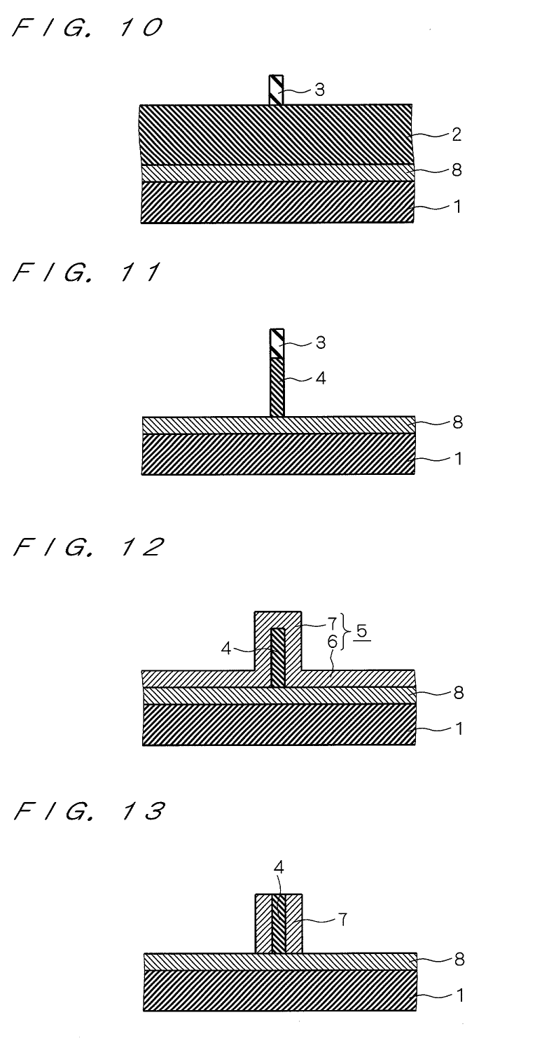

The subsequent step in FIG. 11 is anisotropic etching using the mask 3 to selectively remove the insulating film 2. As a result, the insulating columnar body 4 is formed standing on the part of the lower interconnect line 8. This step is followed by the step in FIG. 12 providing the conductive film 5 to cover the underlying layer 1, the lower interconnect line 8 and the columnar body 4 in a skin-like manner.

Thereafter in FIG. 13, anisotropic etching is performed on the entire surface of an intermediate structure resulting from the step in FIG. 12 to remove the portion 6 of the conductive film 5 defined to cover the underlying layer 1. Also removed in this step is the portion of the conductive film 5 in the area for covering the head of the columnar body 4. As the removal in this step requires anisotropic etching, the conductive film 5 remains without subjection to removal in the area for covering the side surfaces of the columnar body 4 (remained part is the tubular portion 7). In order to remove the portion 6 of the conductive film 5 while avoiding totally removing the lower interconnect line 8, it is desirable that the lower interconnect line 8 is large in thickness. Alternatively, it is desirable as well that the lower interconnect line 8 and the conductive film 5 are made of different materials to improve etching selectivity. In this case, metal such as aluminum or the alternative including aluminum as a main constituent may be used as the lower interconnect line 8 and metal such as tungsten or the alternative including tungsten as a main constituent as the conductive film 5. When the lower interconnect line 8 and the conductive film 5 are made of the same material, such material may be tungsten or the alternative metal including tungsten as a main constituent. It is desirable in the second preferred embodiment as well as in the first preferred embodiment that the conductive film 5 is made of a material exhibiting some degree of excellence in coverage characteristic.

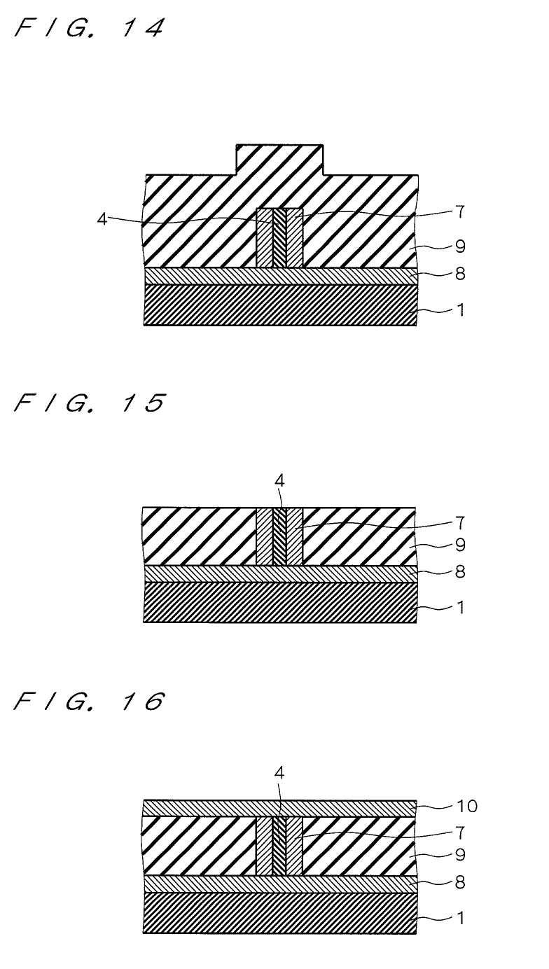

The subsequent step in FIG. 14 is provision of the interlayer insulating film 9 on the underlying layer 1 to bury the lower interconnect line 8, the columnar body 4 and the conductive film 7. This step is followed by the step in FIG. 15 polishing the upper surface of the interlayer insulating film 9 to the extent that the conductive film 7 is exposed yet no exposure of the lower interconnect line 8 occurs. The upper surface of the interlayer insulating film 9 is thereby planarized. After this, the upper interconnect line 10 is provided on the interlayer insulating film 9 in such a manner that the upper interconnect line 10 is connected to the tubular portion 7 of the conductive film 5 as illustrated in FIG. 16.

Following the foregoing steps of the manufacturing method, connection between the lower interconnect line 8 and the upper interconnect line 10 can be established without the step of filling a contact hole with a conductive material. As a result, favorable connectivity can be obtained while meeting the need for microstructure of the device element. Further, the method requiring patterning of the lower interconnect line 8 prior to formation of the columnar body 4 facilitates formation of the lower interconnect line 8.

Third Preferred Embodiment

FIGS. 17 through 22 are views illustrating the steps of a method of manufacturing a semiconductor device according to the third preferred embodiment of the present invention. First, a patterned lower interconnect line 21 is formed on the underlying layer 1 as illustrated in FIG. 17. The lower interconnect line 21 is made of a polycrystalline semiconductor doped with an impurity such as polycrystalline silicon. The lower interconnect line 21 may be provided by depositing polycrystalline semiconductor as a material thereof on the underlying layer 1 to form a film and then patterning the same using a known technique. Next, a sacrificial film 22 is provided on the underlying layer 1 to bury the lower interconnect line 21. The sacrificial film 22 is thereafter selectively removed, thereby forming a through hole 23 opened up on a part of the lower interconnect line 21. The sacrificial film means a film to be subjected to removal after used as a mold. The sacrificial film 22 is a resist film, for example. The through hole 23 is formed by the known lithography technique.

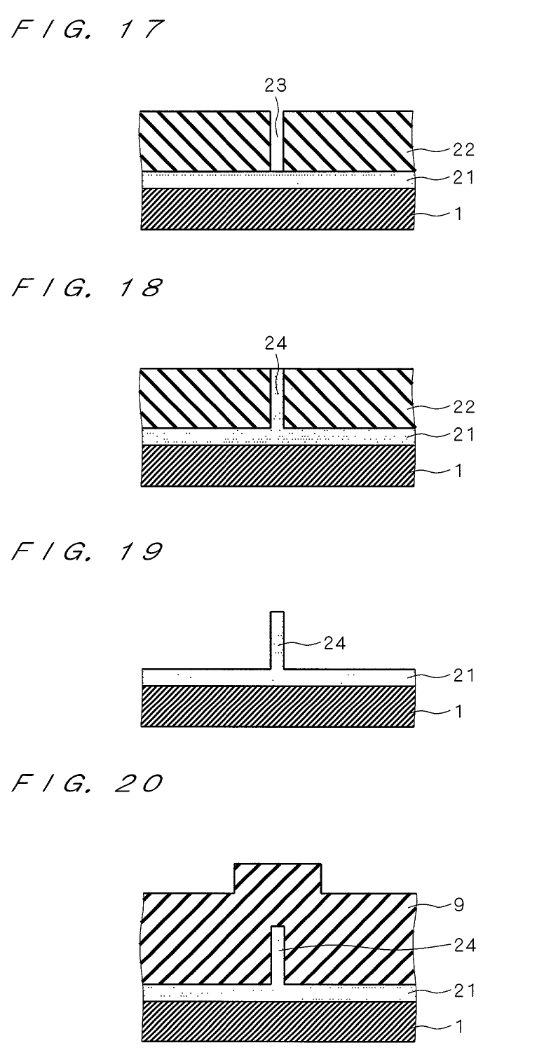

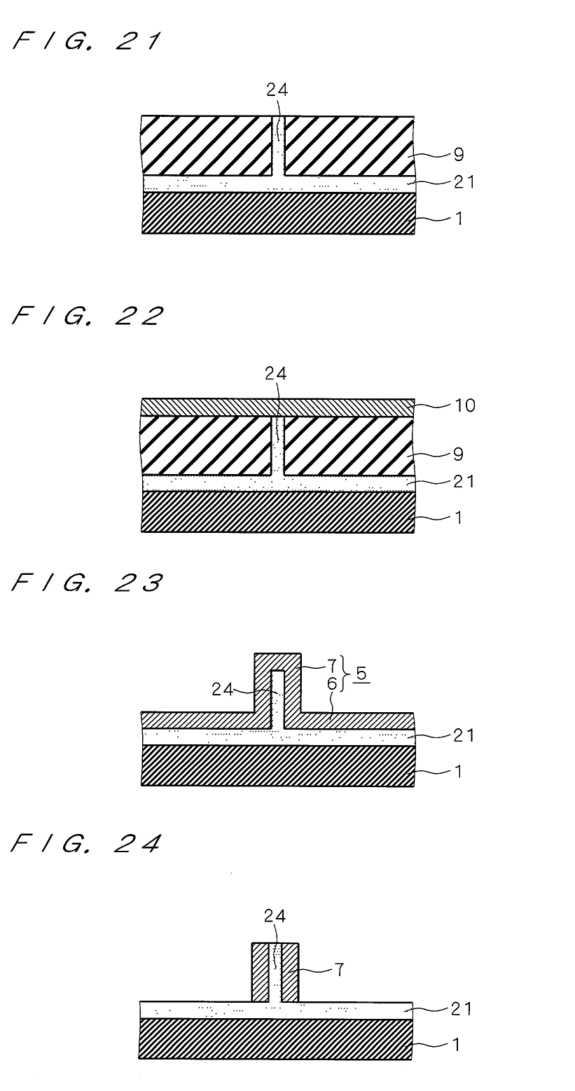

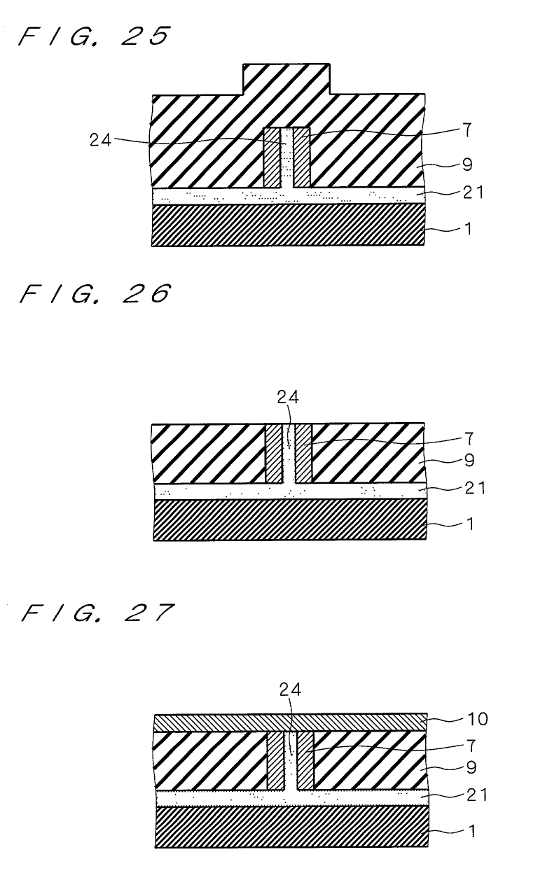

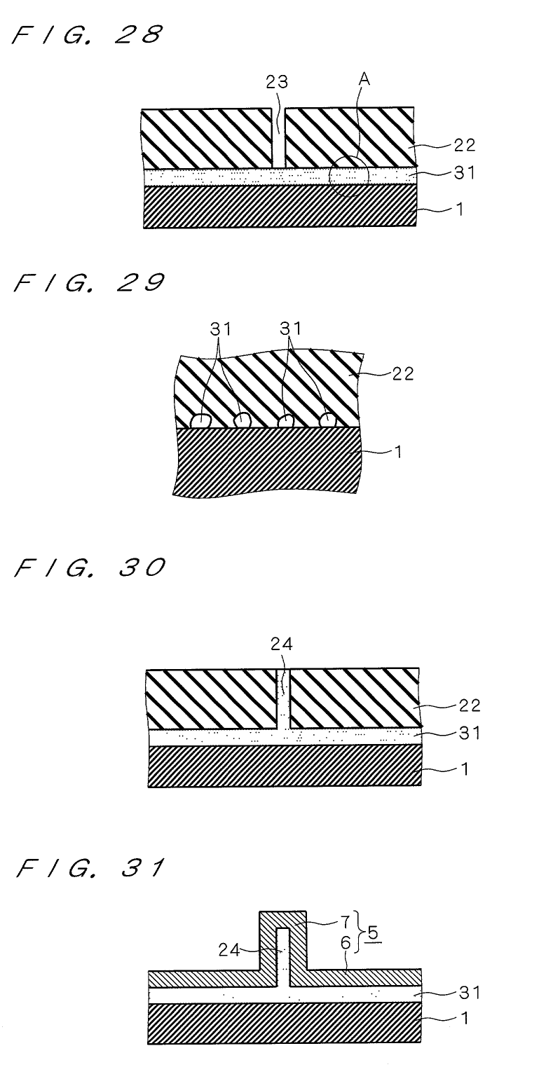

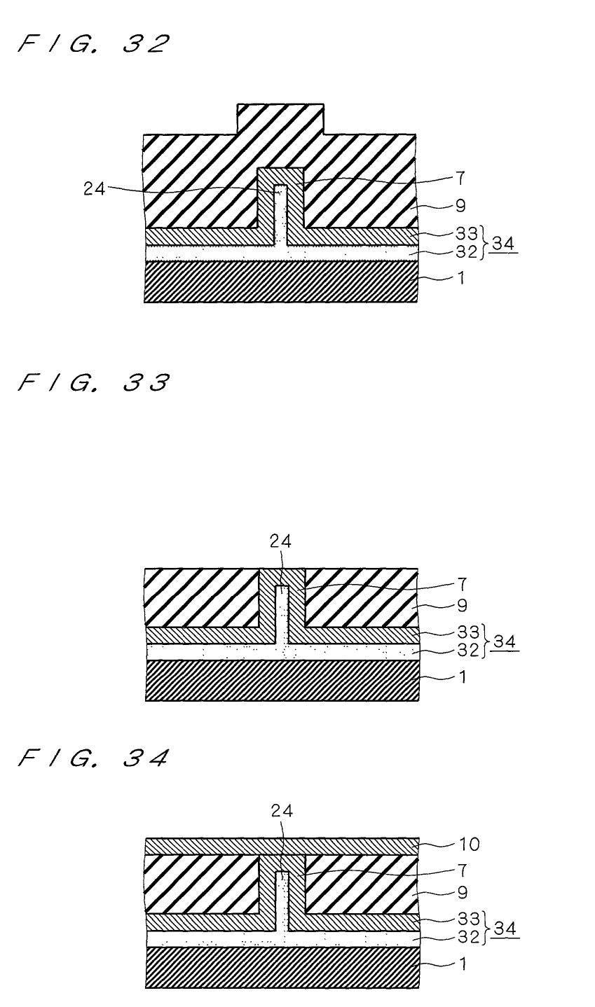

In the subsequent step in FIG. 18, crystal growth of the semiconductor is performed within the through hole 23 using the part of the lower interconnect line 21 exposed to the through hole 23 as a core, thereby providing a columnar body 24 including semiconductor doped with an impurity for filling the through hole 23. The subsequent step in FIG. 19 is removal of the sacrificial film 22. Thereafter the interlayer insulating film 9 is provided on the underlying layer 1 to bury the lower interconnect line 21 and the columnar body 24 as illustrated in FIG. 20. This step is followed by the step in FIG. 21 polishing the upper surface of the interlayer insulating film 9 to the extent that the columnar body 24 is exposed yet no exposure of the lower interconnect line 21 occurs. The upper surface of the interlayer insulating film 9 is thereby planarized. In the subsequent step in FIG. 22, the upper interconnect line 10 is provided on the interlayer insulating film 9 in such a manner that the upper interconnect line 10 is connected to the columnar body 24.

Following the foregoing steps of the manufacturing method, connection between the lower interconnect line 21 and the upper interconnect line 10 can be established without the step of filling a contact hole with a conductive material. As a result, favorable connectivity can be obtained while meeting the need for microstructure of the device element. Further, the method requiring patterning of the lower interconnect line 21 prior to formation of the columnar body 24 facilitates formation of the lower interconnect line 21.

Fourth Preferred Embodiment FIGS. 23 through 27 are views illustrating the steps of a method of manufacturing a semiconductor device according to the fourth preferred embodiment of the present invention. The step in FIG. 23 is performed after following the steps in FIGS. 17 through 19. In the step in FIG. 23, the conductive film 5 is provided to cover the underlying layer 1, the lower interconnect line 21 and the columnar body 24 in a skin-like manner. Namely, the thickness of the conductive film 5 is set to be smaller than the height of the columnar body 24. The conductive film 5 is made of a material having a conductivity higher than that of the columnar body 24 including a semiconductor doped with an impurity. It is desirable in the fourth preferred embodiment as well as in the first preferred embodiment that the material for the conductive film 5 exhibits some degree of excellence in coverage characteristic. For this reason, similar to the first preferred embodiment, tungsten or the alternative metal including tungsten as a main constituent can be a desirable material for the conductive film 5, for example.

Thereafter in FIG. 24, anisotropic etching is performed on the entire surface of an intermediate structure resulting from the step in FIG. 23 to remove the portion 6 of the conductive film 5 defined to cover the underlying layer 1 and the lower interconnect line 21. Also removed in this step is the tubular portion 7 of the conductive film 5 in the area for covering the head of the columnar body 24. As the removal in this step requires anisotropic etching, the tubular portion 7 remains without subjection to removal in the area for covering the side surfaces of the columnar body 24.

The subsequent step in FIG. 25 is provision of the interlayer insulating film 9 on the underlying layer 1 to bury the lower interconnect line 21, the columnar body 24 and the tubular portion 7. This step is followed by the step in FIG. 26 polishing the upper surface of the interlayer insulating film 9 to the extent that the columnar body 24 is exposed yet no exposure of the lower interconnect line 21 occurs. The upper surface of the interlayer insulating film 9 is thereby planarized. After this, the upper interconnect line 10 is provided on the interlayer insulating film 9 in such a manner that the upper interconnect line 10 is connected to the columnar body 24 and the tubular portion 7 as illustrated in FIG. 27.

Following the foregoing steps of the manufacturing method, connection between the lower interconnect line 21 and the upper interconnect line 10 can be established without the step of filling a contact hole with a conductive material. As a result, favorable connectivity can be obtained while meeting the need for microstructure of the device element. Further, the method requiring patterning of the lower interconnect line 21 prior to formation of the columnar body 24 facilitates formation of the lower interconnect line 21. Still further, as the lower interconnect line 21 and the upper interconnect line 10 are connected through both the columnar body 24 and the tubular portion 7, connection therebetween can be established with low resistance.

Fifth Preferred Embodiment

FIGS. 28 through 34 are views illustrating the steps of a method of manufacturing a semiconductor device according to the fifth preferred embodiment of the present invention. As illustrated in FIG. 28, provided first on the underlying layer 1 is a semiconductor crystal grain layer or a polycrystalline semiconductor layer doped with an impurity as a first layer portion 31. FIG. 29 is a view schematically illustrating a circular portion A in FIG. 28 in an enlarged manner when the first layer portion 31 is a semiconductor crystal grain layer. As seen from FIG. 29, the semiconductor crystal grain layer means a layer including a collection of semiconductor crystal grains having such a density that it fails to form a polycrystalline semiconductor layer. The first layer portion 31 includes a semiconductor such as silicon.

Next, provided on the first layer portion 31 is the sacrificial film 22 which is then selectively removed to form the through hole 23 selectively opened up on the first layer portion 31. Similar to the fourth preferred embodiment, the sacrificial film 22 is a resist film, for example, and the through hole 23 may be formed by the known lithography technique.

In the subsequent step in FIG. 30, crystal growth of the semiconductor is performed within the through hole 23 using a part of the first layer portion 31 exposed to the through hole 23 as a core, thereby forming the columnar body 24 including semiconductor doped with an impurity for filling the through hole 23. Even when the first layer portion 31 is a semiconductor crystal grain layer as illustrated in FIG. 29, crystal growth can be performed using the first layer portion 31 as a core.

The subsequent step in FIG. 31 is removal of the sacrificial film 22, which is followed by provision of the conductive film 5 for covering the first layer portion 31 and the columnar body 24 in a skin-like manner. Namely, the thickness of the conductive film 5 is set to be smaller than the height of the columnar body 24. Similar to the fourth preferred embodiment, the conductive film 5 is made of a material having a conductivity higher than that of the columnar body 24 including semiconductor doped with an impurity. Further, it is desirable that the material for the conductive film 5 exhibits some degree of excellence in coverage characteristic. For this reason, similar to the fourth preferred embodiment, tungsten or the alternative metal including tungsten as a main constituent can be a desirable material for the conductive film 5, for example.

Thereafter in the step in FIG. 32, the portion 6 of the conductive film 5 defined as a second layer portion for covering the first layer portion 31 and the first layer portion 31 are patterned in a same process so that a lower interconnect line 34 of a two-layer structure is formed including a first layer portion 32 and a second layer portion 33 disposed thereon. According to this structure, resistance in the lower interconnect line 34 is low. The patterning for forming the lower interconnect line 34 is performed by the known lithography technique using a resist. Thereafter the interlayer insulating film 9 is provided on the underlying layer 1 to bury the tubular portion 7 of the conductive film 5 for covering the columnar body 24 and the lower interconnect line 34. This step is followed by the step in FIG. 33 polishing the upper surface of the interlayer insulating film 9 to the extent that the tubular portion 7 is exposed yet no exposure of the lower interconnect line 34 occurs. The upper surface of the interlayer insulating film 9 is thereby planarized. After this, the upper interconnect line 10 is provided on the interlayer insulating film 9 in such a manner that the upper interconnect line 10 is connected to the tubular portion 7 as illustrated in FIG. 34.

Following the foregoing steps of the manufacturing method, connection between the lower interconnect line 34 and the upper interconnect line 10 can be established without the step of filling a contact hole with a conductive material. As a result, favorable connectivity can be obtained while meeting the need for microstructure of the device element. Further, as the lower interconnect line 34 and the upper interconnect line 10 are connected through both the columnar body 24 and the tubular portion 7, connection therebetween can be established with low resistance. Still further, it is allowed to keep resistance low as well in the lower interconnect line 34 having a two-layer structure.

As seen from FIG. 33, polishing of the interlayer insulating film 9 is performed to the extent that no exposure of the columnar body 24 occurs. As a result, according to the structure obtained in FIG. 34, the tubular portion 7 is of a closed-tube configuration having an end closed for covering the head of the columnar body 24 to which the upper interconnect line 10 is connected. Therefore, it is allowed to keep resistance low in the connection between the tubular portion 7 and the upper interconnect line 10. Alternatively, the amount of polishing may be controlled in the step in FIG. 33 to the extent that exposure of the columnar body 24 is given. According to the structure obtained by this polishing, the upper interconnect line 10 to be provided in the step in FIG. 34 is connected to the columnar body 24 as well as to the area of the tubular portion 7 for covering the side surfaces of the columnar body 24.

Methods described below are understood as general ideas for above described methods, in which an electronic device having a multilayer interconnection structure is manufactured. The first method has the steps (a) through (g). In the step (a), an insulating film is provided on an underlying layer. In the step (b), the insulating film is selectively removed to form an insulating columnar body standing on the underlying layer. In the step (c), a conductive film is provided to cover the underlying layer and the columnar body in a skin-like manner. In the step (d), a portion of the conductive film for covering the underlying layer is patterned to form a lower interconnect line. In the step (e), after the step (d), an interlayer insulating film is provided on the underlying layer to bury the columnar body and the conductive film. In the step (f), an upper surface of the interlayer insulating film is polished to an extent that a portion of the conductive film for covering the columnar body is exposed yet no exposure of the lower interconnect line occurs. In the step (g), after the step (f), an upper interconnect line is provided on the interlayer insulating film in such a manner that the upper interconnect line is connected to the portion of the conductive film for covering the columnar body.

In the first method, the insulating film is selectively removed to form the insulating columnar body standing on the underlying layer. The lower interconnect line and the upper interconnect line are connected through the conductive film provided to cover the columnar body. Therefore, it is allowed to establish connection between the lower interconnect line and the upper interconnect line without the step of filling a contact hole with a conductive material. Still further, as the conductive film for connecting the lower interconnect line and the upper interconnect line and the lower interconnect line are simultaneously provided, the manufacturing steps can be simplified.

The second method has the steps (a) through (h). In the step (a), a patterned lower interconnect line is provided on an underlying layer. In the step (b), an insulating film is provided on the underlying layer to bury the lower interconnect line. In the step (c), the insulating film is selectively removed to form an insulating columnar body standing on a part of the lower interconnect line. In the step (d), a conductive film is provided to cover the underlying layer, the lower interconnect line and the columnar body in a skin-like manner. In the step (e), anisotropic etching is performed to remove the conductive film yet avoiding removal of the conductive film only in an area for covering side surfaces of the columnar body. In the step (f), after the step (e), an interlayer insulating film is provided on the underlying layer to bury the lower interconnect line, the columnar body and the conductive film. In the step (g), an upper surface of the interlayer insulating film is polished to an extent that the conductive film is exposed yet no exposure of the lower interconnect line occurs. In the step (h), after the step (g), an upper interconnect line is provided on the interlayer insulating film in such a manner that the upper interconnect line is connected to the conductive film.

In the second method, the insulating film is selectively removed to form the insulating columnar body standing on the lower interconnect line. The lower interconnect line and the upper interconnect line are connected through the conductive film provided to cover the columnar body. Therefore, it is allowed to establish connection between the lower interconnect line and the upper interconnect line without the step of filling a contact hole with a conductive material. Still further, as patterning of the lower interconnect line is performed prior to provision of the columnar body, the lower interconnect line can be easily formed.

The third method has the steps (a) through (h). In the step (a), a patterned lower interconnect line is provided on an underlying layer. The lower interconnect line includes a polycrystalline semiconductor doped with an impurity as a material. In the step (b), a sacrificial film is provided on the underlying layer to bury the lower interconnect line. In the step (c), the sacrificial film is selectively removed to form a through hole opened up on a part of the lower interconnect line. In the step (d), a part of the lower interconnect line exposed to the through hole is grown in crystal growth to form a columnar body for filling the through hole and including semiconductor doped with an impurity as a material. In the step (e), after the step (d), the sacrificial film is removed. In the step (f), after the step (e), an interlayer insulating film is provided on the underlying layer to bury the lower interconnect line and the columnar body. In the step (g), an upper surface of the interlayer insulating film is polished to an extent that the columnar body is exposed yet no exposure of the lower interconnect line occurs. In the step (h), after the step (g), an upper interconnect line is provided on the interlayer insulating film in such a manner that the upper interconnect line is connected to the columnar body.

In the third method, the lower interconnect line including polycrystalline semiconductor doped with an impurity as a material is grown in crystal growth within the through hole provided in the sacrificial film. The columnar body standing on the lower interconnect line is thereby formed for connecting the lower interconnect line and the upper interconnect line. As a result, it is allowed to establish connection between the lower interconnect line and the upper connect line without the step of filling a contact hole with a conductive material. Still further, as the patterning of the lower interconnect line is performed prior to provision of the columnar body, the lower interconnect line can be easily formed.

The fourth method has the steps (a) through (j). In the step (a), a first layer portion is provided on an underlying layer. The first layer portion is a semiconductor crystal grain layer or a polycrystalline semiconductor layer doped with an impurity. In the step (b), a sacrificial film is provided on the first layer portion. In the step (c), the sacrificial film is selectively removed to form a through hole selectively opened up on the first layer portion. In the step (d), a part of the first layer portion exposed to the through hole is grown in crystal growth to form a columnar body for filing the through hole. The columnar body includes semiconductor doped with an impurity as a material. In the step (e), after the step (d), the sacrificial film is removed. In the step (f), after the step (e), a conductive film is provided to cover the first layer portion and the columnar body in a skin-like manner. In the step (g), a second layer portion of the conductive film for covering the first layer portion and the first layer portion is patterned to form a lower interconnect line of a two-layer structure. In the step (h), after the step (g), an interlayer insulating film is provided on the underlying layer to bury a portion of the conductive film for covering the columnar body and the lower interconnect line. In the step (i), an upper surface of the interlayer insulating film is polished to an extent that the portion of the conductive film for covering the columnar body is exposed yet no exposure of the lower interconnect line occurs. In the step (j), after the step (i), an upper interconnect line is provided on the interlayer insulating film in such a manner that the upper interconnect line is connected to the portion of the conductive film for covering the columnar body.

In the fourth method, the first layer portion of the lower interconnect line including polycrystalline semiconductor doped with an impurity as a material is grown in crystal growth within the through hole provided in the sacrificial film. The columnar body standing on the first layer portion is thereby formed for connecting the first layer portion and the upper interconnect line. Further, the second layer portion of the lower interconnect line and the upper interconnect line are connected through the conductive film provided to cover the columnar body. As a result, it is allowed to establish connection between the lower interconnect line and the upper interconnect line with low resistance without the step of filling a contact hole with a conductive material. Still further, it is allowed to keep resistance low as well in the lower interconnect line having a two-layer structure.

While the invention has been shown and described in detail, the foregoing description is in all aspects illustrative and not restrictive. It is therefore understood that numerous modifications and variations can be devised without departing from the scope of the invention.

What is claimed is:

1. An electronic device having a multilayer interconnection structure, comprising:
an underlying layer;
a patterned lower interconnect line provided on said underlying layer;
an interlayer insulating film provided on said underlying layer and said lower interconnect line;
an upper interconnect line provided on said interlayer insulating film;
a tubular conductive film penetrating said interlayer insulating film to establish connection between said lower interconnect line and said upper interconnect line; and
an insulating columnar body buried in a hollow of said conductive film and standing on said lower interconnect line.

2. An electronic device having a multilayer interconnection structure, comprising:
an underlying layer;
a patterned lower interconnect line provided on said underlying layer, said lower interconnect line including polycrystalline semiconductor doped with an impurity as a material;
an interlayer insulating film provided on said underlying layer and said lower interconnect line;
an upper interconnect line provided on said interlayer insulating film;
a tubular conductive film penetrating said interlayer insulating film to establish connection between said lower interconnect line and said upper interconnect line; and
a columnar body buried in a hollow of said conductive film and standing on said lower interconnect line, said columnar body including semiconductor doped with an impurity as a material.

3. An electronic device having a multilayer interconnection structure, comprising:
an underlying layer;
a patterned lower interconnect line of a two-layer structure provided on said underlying layer, said two-layer structure including a first layer portion that is a semiconductor crystal grain layer or a polycrystalline semiconductor layer doped with an impurity and a second layer portion provided on said first layer portion;
an interlayer insulating film provided on said underlying layer and said lower interconnect line;
an upper interconnect line provided on said interlayer insulating film;
a tubular conductive film penetrating said interlayer insulating film to establish connection between said upper interconnect line and said second layer portion, said tubular conductive film including a same material as said second layer portion; and
a columnar body buried in a hollow of said conductive film and standing on said first layer portion, said columnar body including semiconductor doped with an impurity as a material.

4. The electronic device according to claim 3,
wherein said conductive film is of a closed-tube configuration having an end closed to which said upper interconnect line is connected.

5. The electronic device according to claim 1,
wherein a material for said conductive film is a metal including tungsten as a main constituent.

6. The electronic device according to claim 2,
wherein a material for said conductive film is a metal including tungsten as a main constituent.

7. The electronic device according to claim 3,
wherein a material for said conductive film is a metal including tungsten as a main constituent.

8. The electronic device according to claim 4,
wherein a material for said conductive film is a metal including tungsten as a main constituent.
